(19) United States
(12) Patent Application Publication
(10) Pub. No.: US 2015/0280097 A1
(43) Pub. Date: Oct. 1, 2015

(54) THERMOELECTRIC CONVERSION GENERATING DEVICE

(71) Applicants: HITACHI CHEMICAL COMPANY, LTD., Tokyo (JP); HONDA MOTOR CO., LTD., Tokyo (JP)

(72) Inventors: Takahiro Jinushi, Tokyo (JP); Masanao Tominaga, Tokyo (JP); Zenzo Ishijima, Tokyo (JP); Masayoshi Mori, Tokyo (JP); Takeshi Yamagami, Wako-shi (JP); Hiroshi Matsuda, Wako-shi (JP)

(73) Assignee: HONDA MOTOR CO., LTD., Tokyo (JP)

(21) Appl. No.: 14/433,766

(22) PCT Filed: Oct. 1, 2013
(86) PCT No.: PCT/JP2013/076706

§ 371 Date: Apr. 6, 2015

(30) Foreign Application Priority Data
Oct. 5, 2012 (JP) 2012-223442
Oct. 5, 2012 (JP) 2012-223445
Oct. 5, 2012 (JP) 2012-223521
Oct. 5, 2012 (JP) 2012-223632

(51) Int. Cl. H01L 35/30

(52) U.S. Cl. CPC H01L 35/30

(57) ABSTRACT

In an airtight container in which the flow tube is arranged inside of the housing, the housing includes the movable plate part in which the deformation part having flexibility is arranged around the inner rigid part, and the thermoelectric conversion module is sandwiched between the inner solid part and inner plate part of the flow tube in the airtight container. By reducing pressure in the airtight container, the deformation part of the movable plate part deforms and the inner plate part contacts the thermoelectric conversion module in a uniformly pressed condition. The inner solid part of the movable plate part is cooled by the cooling part and the inner plate part is heated by supplying the heating fluid in the flow tube, so that the temperature difference occurs in the thermoelectric conversion module, thereby generating electricity.

### TECHNICAL FIELD

The present invention relates to a thermoelectric conversion generating device in which thermal energy is converted to electrical energy by imparting a temperature difference in a thermoelectric conversion module contained in a airtight container.

### BACKGROUND ART

An electrical power generating technique is known in which thermal energy is converted to electrical energy by using a thermoelectric conversion element. The thermoelectric conversion element is an element using the Seebeck effect, in which a temperature difference is produced between separated parts, and a difference in voltages is generated between the high temperature part and the low temperature part. The amount of power generated increases as the temperature difference increases. Such a thermoelectric conversion element is used in a construction of a so-called “thermoelectric conversion element module”, in which multiple elements are joined. A thermoelectric conversion generating device is constructed in which the thermoelectric conversion module is arranged between a tabular member of a heating side and a tabular member of a cooling side, and the tabular member of the heating side is heated and the tabular member of the cooling side is cooled so as to produce a temperature difference in the thermoelectric conversion module, thereby producing electricity from the thermoelectric conversion module (See Japanese Unexamined Patent Application Publication No. 2009-088408).

In a power generating device of this kind, it is known that the amount of power generated increases as the temperature difference applied to the thermoelectric conversion module increases, as mentioned above, thereby improving power generating performance. As one method to increase the temperature difference of a thermoelectric conversion module, a method is effective in which tabular members of the heating side and the cooling side arranged on both sides of the thermoelectric conversion module are contacted tightly and uniformly on the thermoelectric conversion module so as to increase thermal conductivity via these tabular members.

For example, as disclosed in the above publication, it is possible that each tabular member is tightly contacted on the thermoelectric conversion module in a pressed condition using a fastening member such as a tie rod or a nut. However, in a case in which such members are used, it may be difficult to press the tabular member on the thermoelectric conversion module with a uniform pressure, and a structure of the device may be complicated and cost may increase. In addition, there may be a case in which freedom of layout or design is limited, and furthermore, it may be disadvantageous if a device is attached to an apparatus which is required to be of reduced weight.

### SUMMARY OF THE INVENTION

The present invention was made in view of the above circumstances, and a primary object of the invention is to provide a thermoelectric conversion generating device in which the tabular member of heating side and the tabular member of cooling side of the airtight container on both sides of the thermoelectric conversion module, in order to apply a temperature difference to the thermoelectric conversion module, can contact tightly and uniformly onto the thermoelectric conversion module without complicating the device and increasing cost, and in which freedom in planning or design can be improved and weight can be reduced.

A thermoelectric conversion generating device of the present invention has an airtight container in which a tabular member of a heating side and a tabular member of a cooling side are arranged, and a thermoelectric conversion module contained in the airtight container in a condition that the module is arranged between the tabular member of the heating side and the tabular member of the cooling side, in which the thermoelectric conversion module generates electricity by producing a temperature difference in the thermoelectric conversion module by heating the tabular member of the heating side and cooling the tabular member of the cooling side at the same time, and at least one of the tabular member of the heating side and the tabular member of the cooling side is a tabular member of a movable side which contacts to the thermoelectric conversion module in a pressed condition due to a pressure difference between inside and outside of the airtight container that occurs by reducing pressure inside of the airtight container, and the tabular member of the movable side has a rigid part which is rigid and contacted to the thermoelectric conversion module, and a deformation part which is formed while being connected to the rigid part, is deformed by the pressure difference, and renders the rigid part contacting to the thermoelectric conversion module by the deformation of itself.

In the present invention, an assembled condition is completed by reducing pressure inside of the airtight container at a predetermined pressure. Pressure difference occurs between inside and outside of the airtight container by reducing pressure inside. At the tabular member of the movable side having the rigid part and the deformation part, the deformation part deforms by the action of reducing pressure, and the rigid part is pressed by outer pressure, contacted and fitted tightly to the thermoelectric conversion module. Since the tabular member of the movable side is tightly fitted to the thermoelectric conversion module without using a fastening member such as tie rod or nut, the tabular member of the movable side can be tightly fitted to the thermoelectric conversion module in a uniformly pressed condition without complicating the device and increasing cost. Furthermore, since a fastening member such as bolt or nut is not used, freedom in planning or designing can be improved, and the weight can be reduced.

Furthermore, by the tabular member of the movable side of the present invention, since the part which is fitted to the thermoelectric conversion module is the rigid part, it can be reliably contacted to the thermoelectric conversion module by the surface without being deformed, and therefore, it can be uniformly pressed to the thermoelectric conversion module. In addition, since the pressure inside of the airtight container is reduced, the inside of the airtight container is less easily heated compared to a case in which gas such as air exists inside at ordinary pressure, trouble such that the airtight container is adversely affected by expansion of inner gas, or the thermoelectric conversion module is deteriorated by being heated, can be prevented.

The present invention includes an aspect in which tabular member thickness of the deformation part is smaller than that of the rigid part, and therefore the deformation part can be deformed. In this aspect, the deformation part can be easily formed.

Furthermore, the present invention includes an aspect in which the tabular member of the cooling side is the tabular member of the movable side, and a fin for promoting cooling is arranged on the rigid part. In this aspect, cooling effect of the tabular member of the cooling side is improved and the temperature difference which occurs in the thermoelectric conversion module becomes greater, thereby improving power generating performance furthermore. Furthermore, stiffness of the rigid part is increased by the fin, thereby preventing the rigid part from being deformed further. In addition, the fin can be fixed easily since the part to be fixed is the rigid part.

Furthermore, the present invention includes an aspect in which the deformation part is arranged in a condition extending laterally from outside of peripheral surface of the rigid part which is opposite side to the thermoelectric conversion module side, and the peripheral surface of the rigid part is formed into an approximately tapered shape projecting laterally from the outside to the inside which is the thermoelectric conversion module side. In this aspect, the deformation part which deforms by the action of reducing pressure becomes less likely to be interfered with the peripheral surface of the rigid part, and damage such as fracture or crack is less likely to occur in the deformation part.

Furthermore, the present invention includes an aspect in which the airtight container includes a hollow part surrounded by the tabular member of the heating side, the thermoelectric conversion module is arranged around the hollow part, the tabular member of the cooling side is arranged outside of the thermoelectric conversion module, and a heating fluid flows through the hollow part so as to heat the tabular member of heating side. In this aspect, the tabular member of the heating side can be efficiently heated by flowing the heating fluid in the hollow part without scattering the heating fluid.

Furthermore, the present invention includes an aspect in which the thermoelectric conversion module is not joined to the rigid part. In this aspect, in a case in which the thermoelectric conversion module or the rigid part expands or contracts by heating and cooling, since the rigid part and the thermoelectric conversion module are not joined therebetween, they can be relatively moved while being contacted, as a result, no disadvantages of deformation due to stress by the influence of heat occur.

Furthermore, the present invention includes an aspect in which the deformation part is an elastic part which is elastically deformed so that the rigid part is elastically pressed and contacted to the thermoelectric conversion module side. In this aspect, also by the action of the deformation part, the rigid part contacts to the thermoelectric conversion module by a pressed condition and fits tightly, and thus the fitting property of the rigid part to the thermoelectric conversion module is further improved.

Furthermore, the present invention includes an aspect in which the an elastic member is included, which renders one tabular member of the tabular member of the heating side and the tabular member of the cooling side being pressed and contacted to the thermoelectric conversion module. In this aspect, also by the action of the elastic member, the rigid part contacts to the thermoelectric conversion module by a pressed condition and fits tightly, and thus the fitting property of the rigid part to the thermoelectric conversion module is further improved.

Furthermore, the present invention includes an aspect in which a pressing plate is arranged on outer surface side of the tabular member which is pressed and contacted to the thermoelectric conversion module by the elastic member, and the elastic member is sandwiched between the pressing plate and the tabular member. In this aspect, by pressing the pressing plate against repulsive force of the elastic member to the tabular member side, and fixing thereon, thereby imparting the repulsive force of the elastic member and holding there, thus, the repulsive force of the elastic member can be reliably imparted to the thermoelectric conversion module.

Furthermore, the present invention includes an aspect in which the elastic member is joined to one of the tabular member and the pressing plate, and is not joined to the other of them. In this aspect, since the elastic member is joined to one of the tabular member and the pressing plate, the elastic member can be easily handled and assembled. In addition, in a case in which the thermoelectric conversion module or the tabular member expands or contracts by heating and cooling, since the part of the elastic member which is not joined can be moved relatively to the thermoelectric conversion module or the tabular member, disadvantages of deformation due to stress by the influence of heat is less likely to occur.

Furthermore, the present invention includes an aspect in which the tabular member is the tabular member of cooling side, a cooling medium is flowed between the tabular member and the pressing plate, and the cooling medium contacts to the elastic member. In this aspect, temperature of the tabular member of the cooling side is conducted to the elastic member, the elastic member is cooled by the cooling medium, and cooling efficiency of the tabular member of the cooling side is improved. That is, heat radiation effect can be obtained by the elastic member. Therefore, in this case, the elastic member is desirably formed into a fin shape for promoting cooling. As such a fin shape, cross section of corrugated, letter V shaped, letter U shaped, or letter Q shaped can be mentioned.

Furthermore, the present invention includes an aspect in which the tabular member of the movable side is the tabular member of the cooling side, a cooling chamber is arranged in which a cooling fluid is supplied and contacted to the tabular member of the cooling side, and the rigid part of the tabular member of the cooling side is contacted to the thermoelectric conversion module in a pressed condition due to inner pressure generated in the cooling chamber by the cooling fluid. In this aspect, the rigid part of the tabular member of the cooling side is contacted to the thermoelectric conversion module in a pressed condition due to inner pressure of the cooling chamber which is generated by supplying the cooling medium, fitting property of the rigid part to the thermoelectric conversion module can be further improved. In addition, since pressing force from the tabular member of the cooling side can be conducted to the tabular member of the heating side via the thermoelectric conversion module, it is also possible that the tabular member of the heating side is tightly fitted to the thermoelectric conversion module in a uniformly pressed condition.

According to the present invention, the thermoelectric conversion generating device can be provided, in which each tabular member of the heating side and the cooling side of the airtight container arranged on both sides of the thermoelectric conversion module in order to produce a temperature difference in the thermoelectric conversion module can be tightly fitted to the thermoelectric conversion module in a uniformly pressed condition without complicating the device and increasing cost, and in addition, freedom in planning or designing can be improved and weight can be reduced.

### BRIEF DESCRIPTION OF DRAWING

FIG. 1 is an overall oblique view of the thermoelectric conversion generating device according to the First Embodiment of the present invention.

FIG. 2 is an oblique view showing a condition in which an outer cover and sealing cover are detached in the thermoelectric conversion generating device of the First Embodiment.

FIG. 3 is a side view of the thermoelectric conversion generating device of the First Embodiment.

FIG. 4 is a cross sectional view at IV-IV in FIG. 3.

FIG. 5 is a front view of the thermoelectric conversion generating device of the First Embodiment.

FIG. 6 is a cross sectional view at VI-VI in FIG. 5.

FIG. 7A is a front view and FIG. 7B is a side view of a generating unit constructing the thermoelectric conversion generating device of the First Embodiment.

FIGS. 8A and 8B are a cross sectional view conceptually showing the structure of a main part of the airtight container in the generating unit, FIG. 8A shows a condition before reducing pressure inside of the airtight container, and FIG. 8B shows a condition of reducing pressure inside of the airtight container.

FIG. 9 is a cross sectional view showing a variation of the First Embodiment, in which a peripheral surface of an inner rigid part is made a tapered shape.

FIGS. 10A and 10B are is a cross sectional view showing a variation of the First Embodiment, in which a deformation part of a movable plate part is made circular (FIG. 10A shows a condition before reducing pressure inside of the airtight container, and FIG. 10B shows a condition of reducing pressure inside of the airtight container.).

FIGS. 11A and 11B are a cross sectional view conceptually showing a structure of the airtight container and an end part cooling part in the generating unit of thermoelectric conversion generating device of the Second Embodiment of the present invention, FIG. 11A shows a condition before joining a cooling case, and FIG. 11B shows a condition in which the cooling case is joined and an inner rigid part of a movable plate part is pressed to the thermoelectric conversion module by an elastic plate.

FIG. 12 is a cross sectional view conceptually showing a structure of the airtight container and an intermediate cooling part of the generating unit of the Second Embodiment, and showing a condition in which the inner rigid part is pressed to the thermoelectric conversion module by an elastic plate which is sandwiched between inner rigid parts of the movable plate part.

FIGS. 13A and 13B are a cross sectional view showing a variation of the elastic plate of the Second Embodiment, FIG. 13A shows a condition before the cooling case is joined, and FIG. 13B shows a condition in which the cooling case is joined and an inner rigid part of a movable plate part is pressed to the thermoelectric conversion module by an elastic plate.

FIGS. 14A and 14B are a view showing another variation of the elastic plate of the Second Embodiment, FIG. 14A shows a condition before the cooling case is joined, and FIG. 14B shows a condition in which the cooling case is joined and an inner rigid part of a movable plate part is pressed to the thermoelectric conversion module by an elastic plate.

FIGS. 15A and 15B are a cross sectional view conceptually showing a vicinity of an end part cooling part in a generating unit of the thermoelectric conversion generating device of the Third Embodiment of the present invention, FIG. 15A shows a condition before reducing pressure inside of the airtight container, and FIG. 15B shows a condition of reducing pressure inside of the airtight container.

FIG. 16 is a cross sectional view conceptually showing a vicinity of the intermediate cooling part in the generating unit of the Third Embodiment, and shows a condition of reducing pressure inside of the airtight container.

FIG. 17A is a front view and FIG. 17B is a side view of a generating unit constructing the thermoelectric conversion generating device of the Fourth Embodiment of the present invention.

FIGS. 18A and 18B are a cross sectional view conceptually showing the structure of a main part of the airtight container of a generating unit of the Fourth Embodiment, FIG. 18A shows a condition before joining a movable plate part of the housing, and FIG. 18B shows a condition in which the movable plate part is joined and an inner rigid part is fitted on the thermoelectric conversion module in a pressed condition.

FIGS. 19A and 19B are a cross sectional view showing a variation of the Fourth Embodiment, that is, the variation in which a spring plate constructing elastic part of the movable plate part is circular, FIG. 19A shows a condition before the movable plate part is joined, and FIG. 19B shows a condition in which the movable plate part is joined.

### EXPLANATION OF REFERENCE SYMBOLS

1: Thermoelectric conversion generating device, 3: Airtight container, 31: Movable plate part of housing (tabular member of cooling side, tabular member movable side), 312: Inner rigid part (rigid part), 312b: Peripheral surface, 313: Deformation part, 317: Elastic part, 351: Hollow part, 36: Inner plate part of flow tube (tabular member of heating side), 4: Thermoelectric conversion module, 53B: Cooling case (pressing plate), 53a, 53b: Cooling jacket (cooling chamber), 7: Fin, 70: Elastic plate (elastic member), H: Heating fluid, W: Cooling water (fluid for cooling).

### BEST MODE FOR CARRYING OUT THE INVENTION

Next, the First to Fourth Embodiments of the present invention are explained with reference to the drawings.

### First Embodiment

### [1-1] Overall structure of Thermoelectric Conversion Generating Device

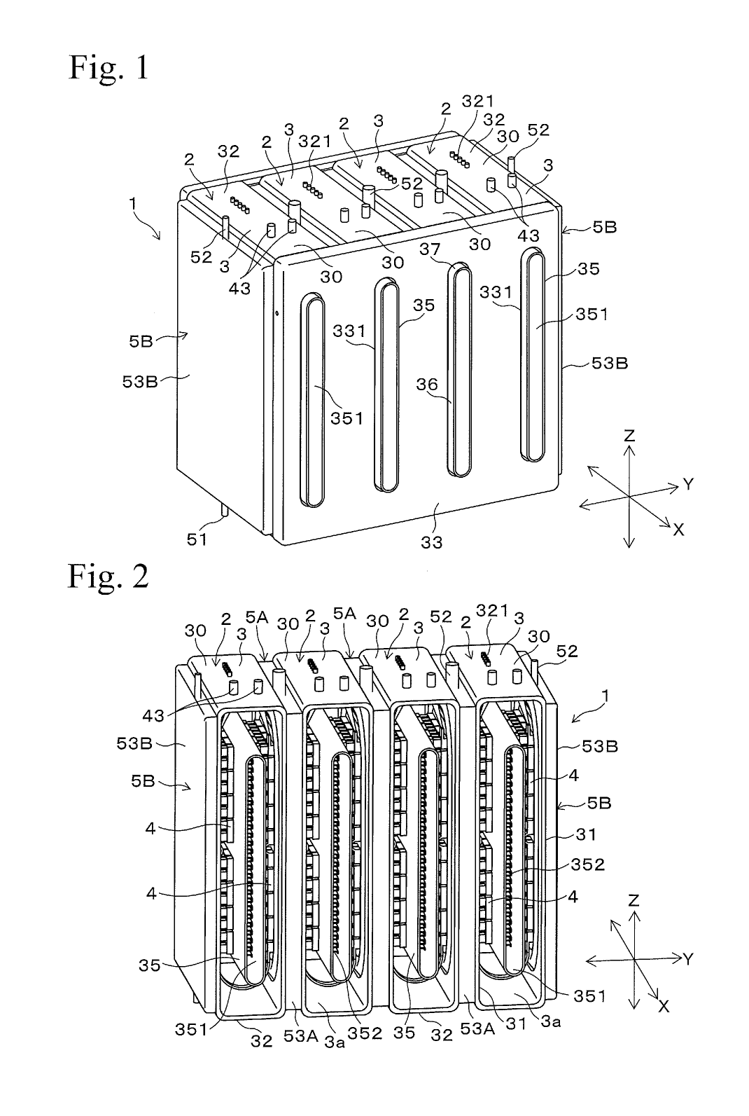

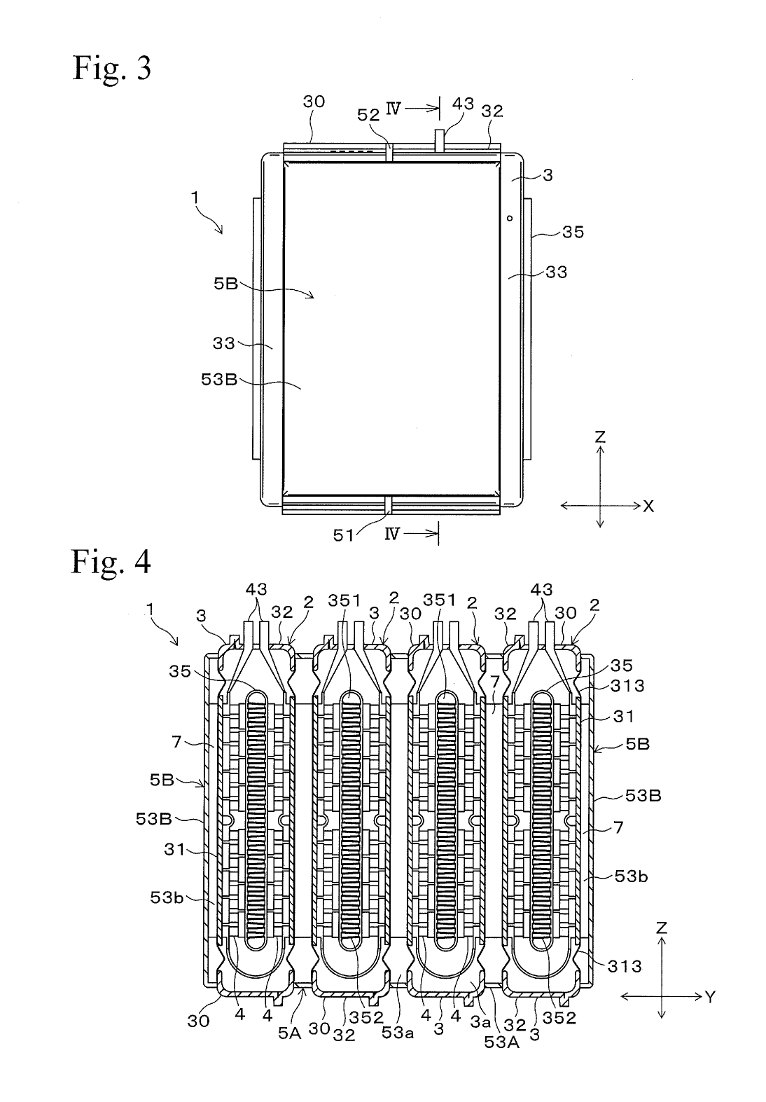

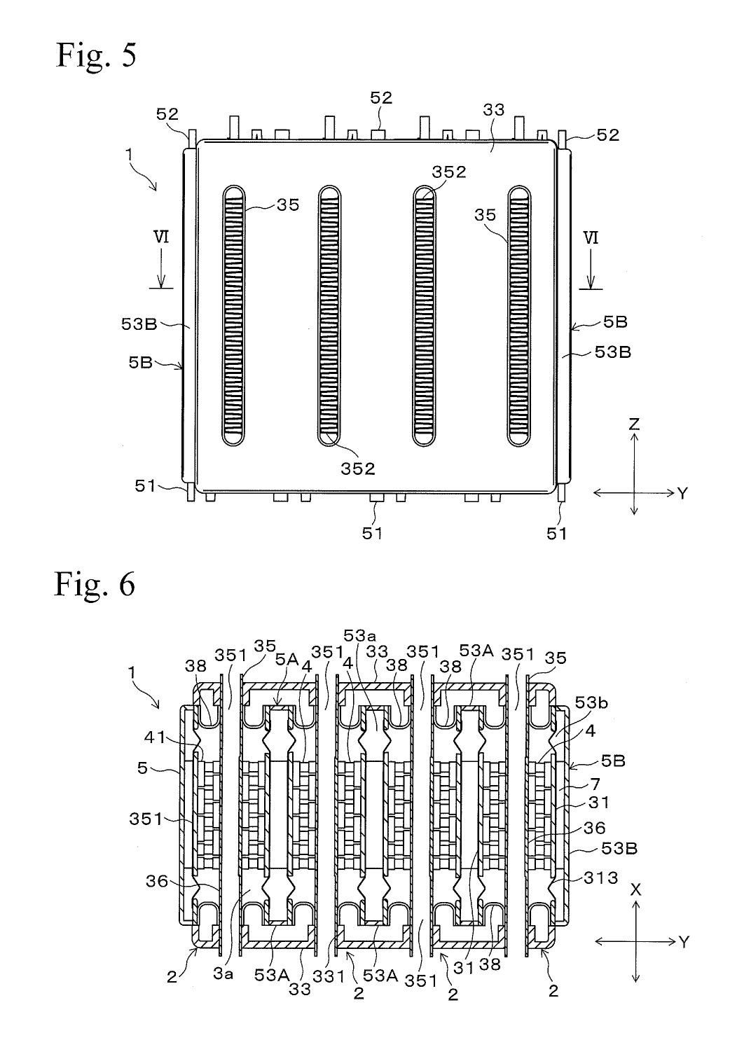

FIGS. 1 to 6 show the thermoelectric conversion generating device (hereinafter referred to as a “generating device”) 1 of the First Embodiment. This generating device 1 has a structure in which multiple generating units 2 each having an airtight container 3 are layered parallel along the Y direction with each unit sandwiching a cooling part 5A therebetween, and a cooling part 5B is also arranged at both side surfaces of the overall device 1, that is, both end parts along the Y direction. The number of generating unit 2 can be freely selected, and in this case, the structure of the generating device 1 is shown, in which four generating units 2 are layered.

The airtight container 3 is constructed by a housing 30 having approximately cuboid box shape being longer along the Z direction in a cross section (Y-Z cross section), a flow tube 35 having a flat tube shape that is longer along the Z direction in a cross section arranged at a central part in the housing 30, and sealing cover 38 (see FIG. 6) sealing openings of both ends along the X direction. Both of the housing 30 and the flow tube 35 have openings at both ends along the X direction, and inside of the flow tube 35 forms a hollow part 351 in which heating fluid mentioned below flows along the X direction.

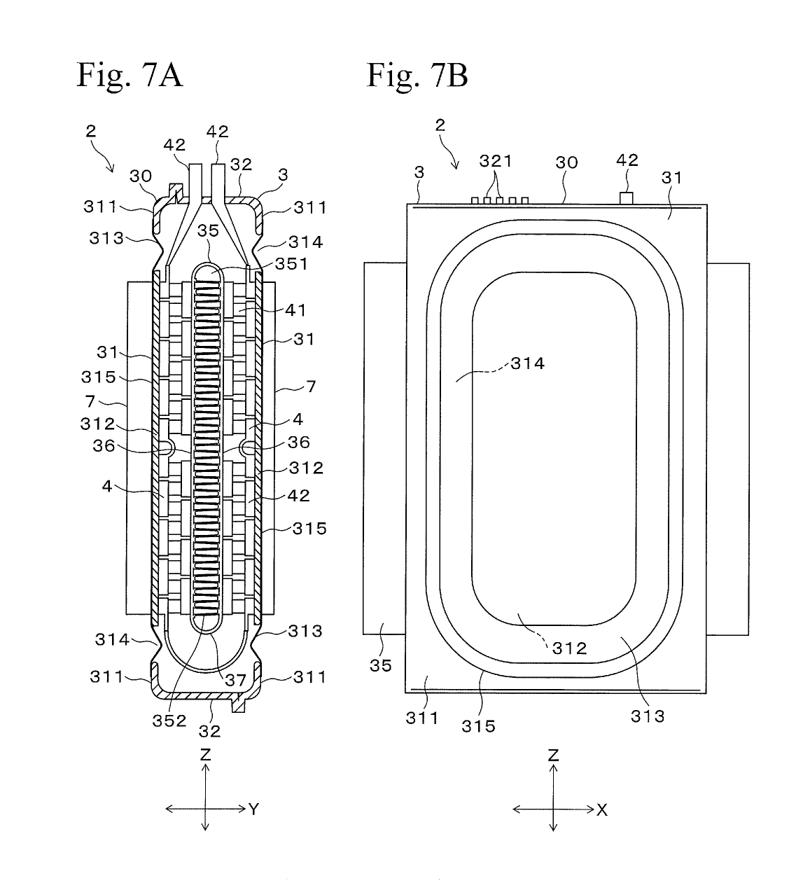

As shown in FIG. 7, the housing 30 is formed in approximately cuboid box shape by a pair of movable plate parts (tabular member of cooling side of the present invention, that is, tabular member of movable side) 31 facing each other and parallel to the X-Z plane, and a pair of end plate parts 32 having a flat planar shape and connecting upper and lower edges of the movable plate parts 31. In addition, the flow tube 35 is formed in a flat tube shape by a pair of inner plate parts (tabular member of heating side) 36 facing each other and parallel to the X-Z plane, and a pair of bending parts 37 having a half-circular arc shape cross section and connecting upper and lower edges of the inner plate parts 36.

Inside of the flow tube 35, that is, in the hollow part 351 of the airtight container 3, fins 352 are arranged. The fin 352 is formed in a corrugated plate shape by bending a tabular material and is joined by a joining means such as brazing in a condition that outside of the bent parts are contacted on an inner surface of the inner plate part 36.

Inside of the airtight container 3, that is, between the inner surface of the housing 30 and the outer surface of the flow tube 35, an inner space 3a is formed having an approximately circular shape in which longitudinal cross section is longer along the Z direction. At both sides of the Y direction in the inner space 3a, the thermoelectric conversion modules 4 are arranged in each space in a condition in which the module is sandwiched between the movable plate part 31 of the housing 30 and the inner plate part 36 of the flow tube 35.

The multiple airtight containers 3 each having the inner space 3a in which the thermoelectric conversion modules 4 are arranged making pairs in the both regions of the Y direction, are layered in parallel along the Y direction in a condition that the cooling part 5A is sandwiched between the movable plate parts 31, as shown in FIGS. 4 and 6. Furthermore, the cooling part 5B is also arranged on each of the outer surfaces of the movable plate part 31 of both ends along the Y direction. Hereinafter, the cooling part 5A between the airtight containers 3 is called an “intermediate cooling part 5A”, and the cooling part 5B at the both ends of the Y direction is called an “end part cooling part 5B”.

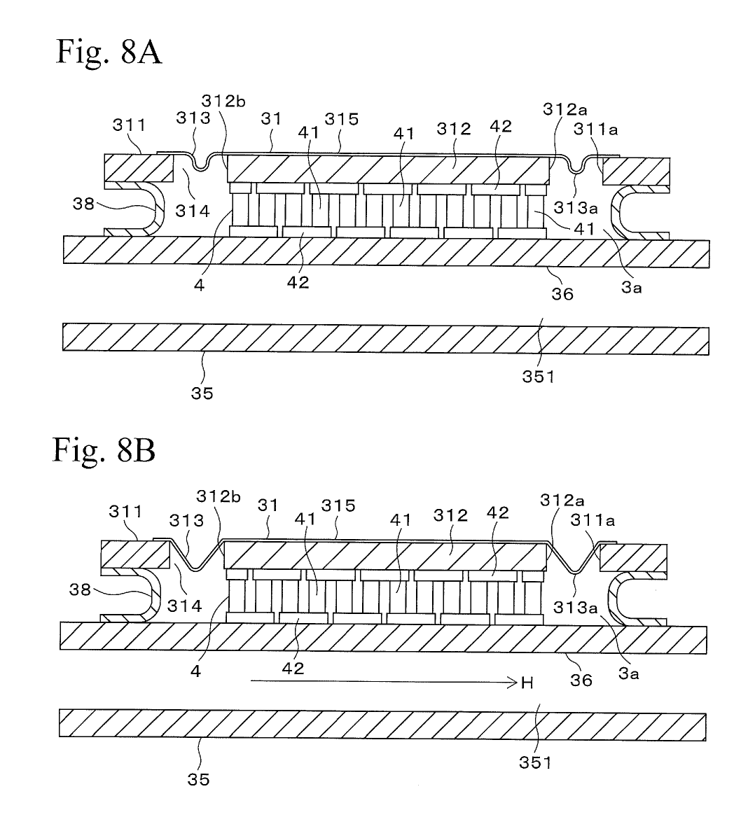

As shown in FIG. 8, the thermoelectric conversion module 4 is constructed in which of the side surfaces and the other of the side surfaces of the multiple thermoelectric conversion elements 41 arranged to be planar are connected in a zigzag by electrodes 42 made of, for example, copper, and the electrodes 42 of one surface side are joined to the inner surface of the inner plate part 36 of the flow tube 35 by a joining means such as brazing. Furthermore, the electrodes 42 of the other surface side of the thermoelectric conversion module 4 contacts the inner surface of an inner rigid part 312 explained below of the movable plate part 31 of the housing 30. That is, the thermoelectric conversion module 4 is not joined to the inner rigid part 312, and they can be relatively moved along the contacting surface thereof.

As a thermoelectric conversion element 41 constructing the thermoelectric conversion module 4, a kind having high heatproof temperature is used, for example, of the silicon-germanium type, magnesium-silicon type, manganese-silicon type, iron silicide type is desirably used. A pair of terminals 43 is connected to the thermoelectric conversion module 4 so as to obtain electricity. In this case, as shown in FIG. 7A, the terminals 43 are drawn upward in the upper part of the inner space 3a, and protrude to the outside penetrating the end plate part 32 of the upper side of the airtight container 3. The penetrating hole of the terminal 43 on the end plate part 32 is treated so that the hole is sealed airtight.

As shown in FIG. 6, an opening of the X side of the inner space 3a of the airtight container 3 is sealed by a sealing cover 38 having a U-shaped cross section projecting to the inside and having an oval shape overall. The sealing cover 38 is joined airtight to the inner surface of an outer rigid part 311 mentioned below of the movable plate part 31 and the outer surface of the end part of the X direction of the flow tube 35. The inner space 3a of the airtight container 3 is sealed airtight by the housing 30, the flow tube 35, and the sealing cover 38. Outer cover 33 is joined to both end surfaces in the X direction of the housing 30 of each airtight container 3, that is, both sides in the X direction of the device 1 of the present invention is covered with this outer cover 33. The two end parts in the X direction of each flow tube 35 protrude from the each housing 30, and these protruding end parts protrude to the outside penetrating flow tube inserting hole 331 formed on the outer cover 33.

### [1-2] Structure of Airtight Container

As shown in FIG. 7, the movable plate part 31 constructing the housing 30 of the airtight container 3 includes the outer rigid part 311 which is formed so that the outer shape thereof is a rectangular frame shape, the inner rigid part 312 formed inside of the outer rigid part 311 having a thickness the same as the outer rigid part 311, and a deformation part 313 which is thinner than the rigid parts 311 and 312 and which is arranged to block a gap 314 having a certain width formed between the outer rigid part 311 and the inner rigid part 312.

Inner edge 311a of the outer rigid part 311 is formed approximately in an oval shape, and outer edge 312a of the inner rigid part 312 is formed approximately in an oval shape while being arranged having a certain gap 314 from the inner edge 311a of the outer rigid part 311. Thin plate 315 having flexibility is joined to the outer surface of the inner rigid part 312 by a joining means such as brazing. This thin plate 315 has a size sufficient to cover over the gap 314 between the rigid parts 311 and 312 and to reach the outer surface of the outer rigid part 311, and the outer edge part thereof is joined to the outer surface of the outer rigid part 311 by a joining means such as brazing. A condition is maintained in which the rigid parts 311 and 312 are connected while existing within the same plane by this thin plate 315. In the present Embodiment, the rigid parts 311 and 312 exist in the same plane; however, the relationship of location of the rigid parts. 311 and 312 is not limited to this, and a structure in which they are connected by the thin plate 315 while one of them is shifted to the inside, can be selected.

The part in which the thin plate 315 covers the gap 314 forms the approximately circular deformation part 313 having flexibility, and as shown in FIG. 8, at the central part in the width direction of the deformation part 313, a convex line part 313a protruding to the inside is formed along the entire circumference. The deformation part 313 is arranged so as to extend from the outside of circumference edge surface 312b of the inner rigid part 312 to the outside of inner edge 311 a of the outer rigid part 311. The two edges in the Z direction of the outer rigid part 311 are formed so as to unite with end plate part 32. That is, both sides of the outer rigid parts 311 are integrally formed on a pair of upper and lower end plate parts 32, and the inner rigid part 312 is joined to the outer rigid part 311 via the thin plate 315, so as to construct the housing 30. The inner rigid part 312 has a size sufficient to cover over the thermoelectric conversion module 4 and contacts the entire surface of one side of the thermoelectric conversion module 4.

Multiple outlets for pressure reducing and sealing 321 are arranged on the end plate part 32 of the upper side of the airtight container 3, and pressure in the inner space 3a in the airtight container 3 is reduced by using these outlets for pressure reducing and sealing 321.

The airtight container 3 is sealed airtight by drawing out the air inside of the inner space 3a of the airtight container 3 from an outlet for pressure reduction and sealing 321 so as to reach a predetermined pressure (about 1 to 100 Pa for example), and by welding the outlet for pressure reducing and sealing 321. In this way, pressure difference occurs in the airtight container 3, that is, the pressure inside becomes lower than the outer atmosphere, and the movable plate part 31 of the housing 30 receives a force pressed to the inside by this pressure difference.

FIG. 8A shows a condition in which pressure of the airtight container 3 is reduced. In a case in which the pressure is reduced and the movable plate part 31 is pressed to the inside, a convex line part 313a of the deformation part 313 having flexibility is further deformed protruding to the inside, and thereby the inner rigid part 312 contacts the thermoelectric conversion module 4 strongly and fits tightly and uniformly on the thermoelectric conversion module 4 as shown in FIG. 8B. In other words, the deformation of the deformed part 313 realizes that the contact surface of the inner rigid part 312 on the thermoelectric conversion module 4 moves so as to fit uniformly and tightly on the thermoelectric conversion module 4.

### [1-3] Cooling Part

The intermediate cooling part 5A and the end part cooling part 5B include a cooling case 53A and 53B, respectively. The cooling case 53A of the intermediate cooling part 5A is formed in a frame shape following the circumference edge of the outer rigid part 311 of the movable plate part 31, is sandwiched between neighboring outer rigid parts 311, and is joined to the outer circumference part of these outer rigid parts 311. That is, in the device 1 of the present invention, adjacent housings 30 are in a condition so that adjacent outer rigid parts 311 are mutually joined via the cooling case 53A. A cooling jacket 53a which cools the movable plate part 31 by being a pathway for cooling water is formed inside of the intermediate cooling part 5A that is surrounded by the cooling case 53A and the movable plate parts 31 of both sides sandwiching the cooling case 53A.

On the other hand, the cooling case 53B of the end part cooling part 5B is formed in a lid shape covering the movable plate part 31 of the end part, and the edge thereof is joined to the outer circumferential part of the outer rigid part 311, while a shallow concave part formed on one side is oriented to the movable plate part 31 side. The inside of the end part cooling part 5B, which is surrounded by the inner surface of the cooling case 53B and the movable plate part 31, a cooling jacket 53b which cools the movable plate part 31 by being supplied with cooling water, is formed.

A cooling water supply inlet 51 is formed on the lower end surface of the cooling cases 53A and 53B of the intermediate cooling part 5A and the end part cooling part 5B, and a cooling water exhaust outlet 52 is formed on the upper end surface thereof. The cooling water supply inlet 51 and the cooling water exhaust outlet 52 are formed at the center of the X direction, and a cooling water supply tube and an exhaust tube not shown are connected to the cooling water supply inlet 51 and the cooling water exhaust outlet 52, respectively.

In the cooling jackets 53a and 53b of the intermediate cooling part 5A and the end part cooling part 5B, a fin 7 which is formed in a corrugated shape for example, is contained. One end part of the fin 7 is joined to the inner rigid part 312, and the other end part just contacts the inner surface of the cooling case 53B without being joined.

### [1-4] Operation of Generating Device

In the generating device 1 having the above structure, the cooling water is introduced and flows in the cooling jackets 53a and 53b in order to cool the movable plate part 31 of the airtight container 3. On the other hand, the heating fluid H at high temperature flows through each flow tube 35, from one end to the other end, in order to heat the flow tubes 35. Temperature of the movable plate part 31 that is cooled is conducted to an outer surface side of the thermoelectric conversion module 4, and the outer surface side of the thermoelectric conversion module 4 is cooled. On the other hand, the temperature of the inner plate part 36 of the flow tube 35 that is heated is conducted to the inner surface side of the thermoelectric conversion module 4, and the inner surface side of the thermoelectric conversion module 4 is heated. The heating fluid H is not scattered by flowing in the hollow part 351, and the inner plate part 36 of the flow tube 35 is effectively heated.

In this Embodiment, the movable plate part 31 of the housing 30 functions as the tabular member of the cooling side, and the inner plate part 36 of the flow tube 35 functions as the tabular member of the heating side. As described above, by providing a temperature difference between the outer surface side and the inner surface side of the thermoelectric conversion module 4, the thermoelectric conversion module 4 generates electricity, and the electricity can be obtained from the terminals 43.

For example, exhaust heat gas generated in a factory or garbage incinerator or exhaust gas of vehicles is used as the heating fluid H in the generating device 1 of this Embodiment.

### [1-5] Action and Effect of Airtight Container

In the generating device 1 of this Embodiment, by the pressure difference between inside and outside of the airtight container 3 occurred by reduced pressure inside of the airtight container 3, the inner rigid part 312 of the movable plate part 31 which is merely contacted to the thermoelectric conversion module 4 in a case in which the pressure is not reduced, is contacted to the thermoelectric conversion module 4 while being pressed and fitting tightly and uniformly. By constructing the movable plate part 31 so as to have the inner rigid part 312 contacting to the thermoelectric conversion module 4 and the deformation part 313 having flexibility arranged therearound, the deformation part 313 deforms in a reduced pressure condition, and the inner rigid part 312 may be easily contacted to the thermoelectric conversion module 4 uniformly. Therefore, heat conductivity from the cooling parts 5A and 5B to the thermoelectric conversion module 4 via the inner rigid part 312 of the movable plate part 31 is increased, temperature difference imparted to the thermoelectric conversion module 4 is increased, and power generation efficiency is improved.

In the present Embodiment, unlike in a conventional technique, the inner rigid part 312 of the movable plate part 31 which is the tabular member of the cooling side is tightly fitted to the thermoelectric conversion module 4 by reducing pressure inside of the airtight container 3 without using a member for fastening such as a tie rod or nut, the inner rigid part 312 can be fitted in uniformly pressed condition on the thermoelectric conversion module 4 without complication and high cost. Furthermore, since the member for fastening, such as a bolt and nut, is not used, freedom in planning or designing can be improved and the weight can be reduced.

The inner rigid part 312 which is fitted to the thermoelectric conversion module 4 in a pressed condition by the action of reducing pressure is set to have a thickness not being deformed even if it is pressed to the thermoelectric conversion module 4 side. On the other hand, the deformation part 313 is deformable by conforming movement of the inner rigid part 312 to the inside when pressure inside of the airtight container 3 is reduced. Therefore, the condition can be obtained in which the inner rigid part 312 is prevented from being deformed and the inner rigid part 312 reliably contacts the thermoelectric conversion module 4 by a surface and fits uniformly.

In addition, since pressure inside of the airtight container 3 is reduced, the inside of the airtight container 3 is difficult to heat compared to a case in which the inner space 3a contains gas such as air at normal pressure. Therefore, disadvantages can be reduced in which the airtight container 3 is adversely affected by expansion of inner gas or the thermoelectric conversion module 4 is deteriorated by heating. The deformation part 313 can be easily arranged since the deformation part 313 of the movable plate part 31 is thinner than the inner rigid part 312 and deformable.

Furthermore, the inner rigid part 312 of the movable plate part 31 is tightly fitted to the thermoelectric conversion module 4 but in a condition not joined, and the inner rigid part 312 and the thermoelectric conversion module 4 can move relatively each other along the contacting surface thereof Therefore, in a case in which the thermoelectric conversion module 4 or the inner rigid part 312 expands or contracts by heating and cooling, they moves relatively each other while being contacted along the contacting surface thereof As a result, no disadvantages of deformation due to stress by the influence of heat occur.

Furthermore, since the fin 7 is arranged to the outer surface of the inner rigid part 312 of the movable plate part 31, effect of cooling is improved, temperature difference which occurs in the thermoelectric conversion module becomes greater, thereby improving power generating performance furthermore. Furthermore, stiffness of the rigid part 312 is increased by the fin 7, thereby preventing the rigid part 312 from being deformed further. In addition, the fin 7 can be fixed easily since the inner rigid part 312 is difficult to be deformed.

### [1-6] Variation of First Embodiment

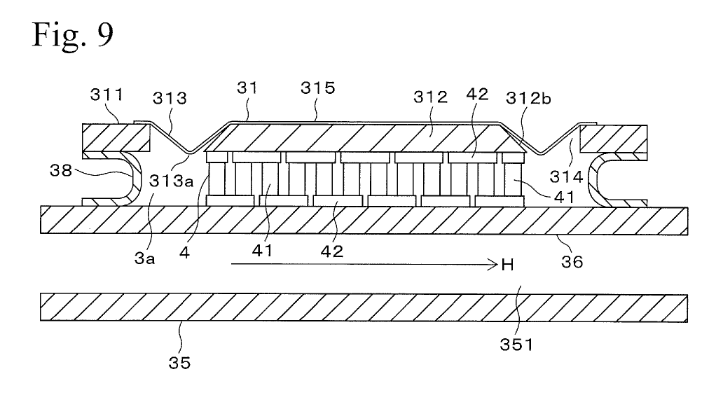

As shown in FIG. 9, the peripheral surface 312b of the inner rigid part 312 of the movable plate part 31 is formed into an approximately tapered shape projecting laterally and aslope from the outside to the inside (in FIG. 9, from the upper side which is opposite to the thermoelectric conversion module 4 side to the lower side which is the thermoelectric conversion module 4 side). According to the structure, the deformation part 313 which deforms to the inside by the action of reducing pressure becomes less likely to be interfered with an angle part of the peripheral surface 312b of the inner rigid part 312 and the outer surface, and damage such as fracture or crack is less likely to occur in the deformation part 313. It should be noted that the tapered peripheral surface 312b has a flat surface in the figure; however, a concavely curved surface or a convexly curved surface from the outside to the inside can be mentioned if necessary.

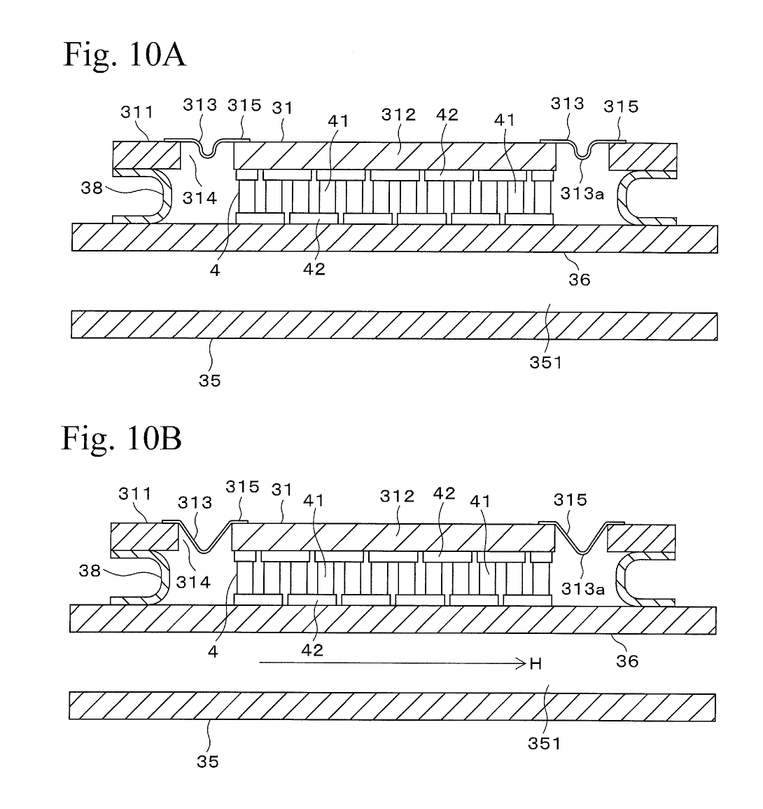

As shown in FIG. 10, the thin plate 315 of the deformation part 313 can be formed into a circular shape having width at least covering the gap 314 between the outer rigid part 311 and the inner rigid part 312, not covering overall outer surface of the inner rigid part 312.

In addition, a buffer material consisting of a flexible material can be arranged, for example, between the thermoelectric conversion module 4 and at least one of the tabular member of the cooling side (the inner rigid part 312 of the movable plate part 31 in the airtight container 3) and the tabular member of the heating side (the inner plate part 36 of the flow tube 35 in the airtight container 3). In such cases, the airtight container 3 contacts the thermoelectric conversion module 4 via the buffer material in a pressed condition and thereby protects the thermoelectric conversion module 4 by the buffer material.

Next, the Second to Fourth Embodiments, having basically the same overall structure as the First Embodiment, are explained. In the following, in explanation about these Embodiments, the same or similar reference numeral is given to a constitutional element similar to that in the First Embodiment referred to in the figure, and explanation thereof is omitted.

### Second Embodiment

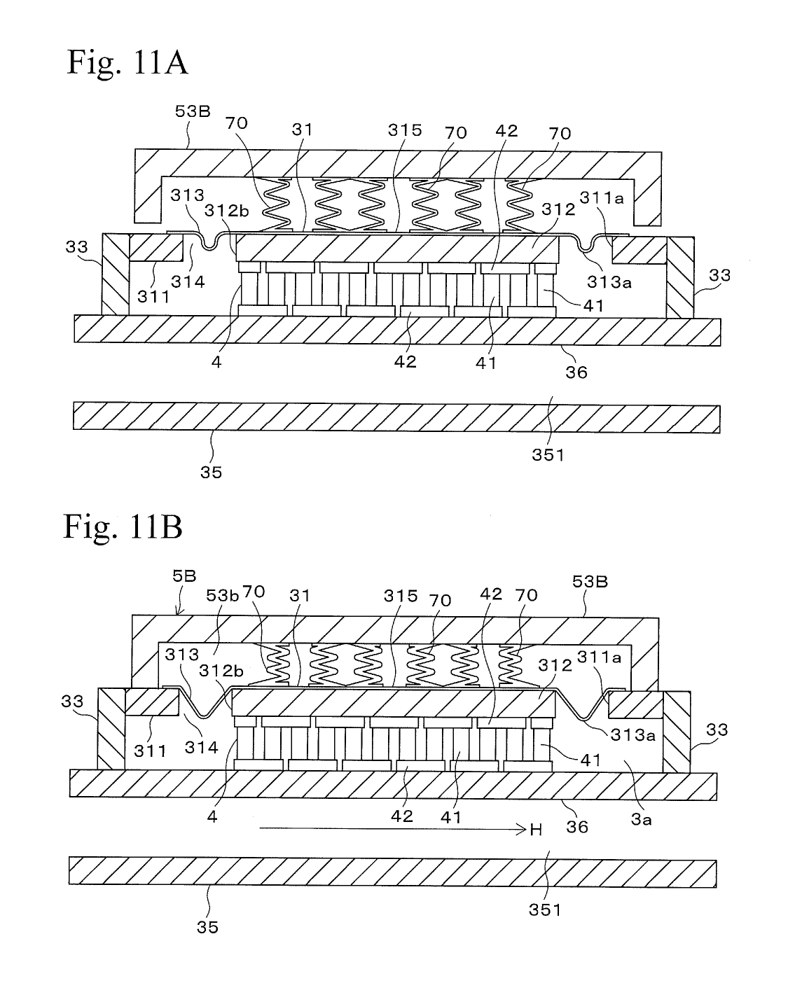

Next, the Second Embodiment of the present invention is explained with reference to FIGS. 11 to 14.

### [2-1] Elastic Plate

In the Second Embodiment, an elastic plate (elastic member) 70 is arranged instead of the fin 7 in the First Embodiment.

As shown in FIG. 11B, in the end part cooling part 5B, the multiple elastic plates 70 are compressed and sandwiched between the cooling case (pressing plate) 53B and the inner rigid part 312. The elastic plate 70 has a fin shape of which the cross section is formed in a corrugated shape, and one end part thereof is joined to the inner surface of the cooling case 53B, and the other end part thereof contacts, but are not joined to, the inner rigid part 312.

FIG. 11A shows a condition before the cooling case 53B is joined to the outer rigid part 311 of the movable plate part 31, and the other end part of the elastic plate 70 which is the inner rigid part 312 side in a free condition contacts to the outer surface of the inner rigid part 312. In this condition, an end part of the cooling case 53B which is to be joined to the outer rigid part 311 is separated from and facing to the outer rigid part 311. The cooling case 53B is moved to the movable plate part 31 side against repulsive force of the elastic plate 70, and the end part thereof for joining is pressed on the outer rigid part 311. While keeping this condition, the end part is joined to the outer rigid part 311. When the cooling case 53B is assembled to the movable plate part 31 in this way, the elastic plate 70 in the cooling jacket 53b is held while being elastically compressed between the cooling case 53B and the inner rigid part 312.

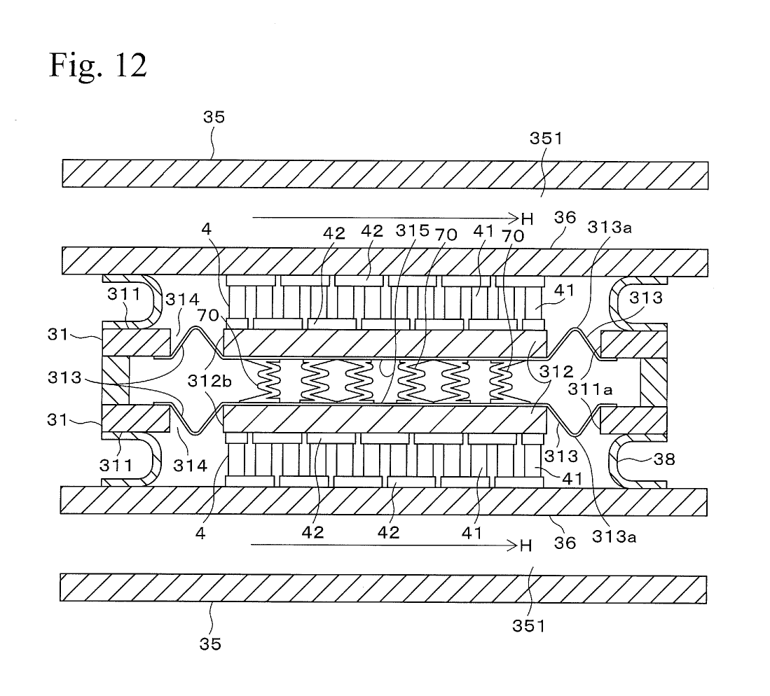

As shown in FIG. 12, with respect to the multiple elastic plates 70 arranged in the cooling jacket 53a of the intermediate cooling part 5A, one end part thereof is joined to one of the inner rigid part 312, and the other end part thereof contacts, but are not joined to, the inner rigid part 312. When adjacent airtight containers 3 are joined each other via the cooling case 53A, the elastic plate 70 of the intermediate cooling part 5A is compressed by moving adjacent inner rigid parts 312 closer each other, and is kept in a condition held between the inner rigid parts 312 after joining.

The airtight container 3 is sealed airtight by drawing out the air inside of the inner space 3a of the airtight container 3 from an outlet for pressure reduction and sealing 321 so as to reach a predetermined pressure (about 1 to 100 Pa for example), and by welding the outlet for pressure reducing and sealing 321. In this way, pressure difference occurs in the airtight container 3, that is, the pressure inside becomes lower than the outer atmosphere, and the movable plate part 31 of the housing 30 receives a force pressed to the inside by this pressure difference.

FIG. 11B shows a condition in which pressure of the inner space 3a of the airtight container 3 is reduced. In a case in which the pressure of the inner space 3a is reduced and the movable plate part 31 is pressed to the inside, a convex line part 313a of the deformation part 313 having flexibility is further deformed protruding to the inside, and thereby the inner rigid part 312 contacts the thermoelectric conversion module 4 strongly and fits tightly and uniformly on the thermoelectric conversion module 4 in addition to repulsive force of the elastic plate 70. In other words, the deformation of the deformed part 313 realizes that the contact surface of the inner rigid part 312 on the thermoelectric conversion module 4 moves so as to fit uniformly and tightly on the thermoelectric conversion module 4.

### [2-2] Action and Effect of Second Embodiment

By the Second Embodiment, the inner rigid part 312 of the movable plate part 31 which is the tabular member of the heating side is pressed due to repulsive force of the elastic plate 70 which is in a compressed condition, and thereby contacts and fits to the thermoelectric conversion module 4. Since the inner rigid part 312 is pressed by the elastic plate 70 and fitted to the thermoelectric conversion module 4 without using a member for fastening such as a tie rod or nut, the inner rigid part 312 can be fitted in uniformly pressed condition on the thermoelectric conversion module 4 without complication and high cost. Furthermore, since the member for fastening such as a bolt and nut is not used, freedom in planning or designing can be improved and the weight can be reduced. Furthermore, stiffness of the inner rigid part 312 can be improved by the elastic plate 70, and the inner rigid part 312 can be prevented from being deformed, and thereby facilitates the inner rigid part 312 to fit the thermoelectric conversion module 4.

The inner rigid part 312 is fitted to the thermoelectric conversion module 4 in a pressed condition also by the action of reducing pressure inside of the airtight container 3. The inner rigid part 312 is set to have a thickness not being deformed even if it is pressed to the thermoelectric conversion module 4 side. On the other hand, the deformation part 313 is deformable by conforming movement of the inner rigid part 312 to the inside when pressure inside of the inner space 3a of the airtight container 3 is reduced. Therefore, the condition can be obtained in which the inner rigid part 312 is prevented from being deformed and the inner rigid part 312 reliably contacts the thermoelectric conversion module 4 by a surface and fits uniformly.

Furthermore, as shown in FIG. 12, the elastic plate 70 that is contained in the cooling jacket 53a of the intermediate cooling part 5A is arranged sandwiched between each inner rigid part 312 of the adjacent airtight container 3. On the other hand, as shown in FIG. 11B, the elastic plate 70 which is contained in the cooling jacket 53b of the end part cooling part 5B generates repulsive force by pressing the cooling case 53B to the housing 30 side, fixing thereon, and holding, thereby imparting the repulsive force of the elastic plate 70 reliably to the thermoelectric conversion module 4.

Furthermore, one end of the elastic plate 70 is joined to the cooling case 53B in the end part cooling part 5B, and is joined to one of the inner rigid parts 312 sandwiching the elastic plate in the intermediate cooling part 5A, and the other end thereof contacts, but is not joined to, the other side. Therefore, handling and assembling of the elastic plate 70 are facilitated. Furthermore, in a case in which the thermoelectric conversion module 4 or the inner rigid part 312 expands or contracts by heating and cooling, the side of the elastic plate 70 that is not joined can move relative to the thermoelectric conversion module 4 or inner rigid part 312, and as a result, no disadvantages of deformation due to stress by the influence of heat occur.

In addition, since pressure in the inner space 3a of the airtight container 3 is reduced, the inner space 3a is difficult to heat compared to a case in which the inner space 3a contains gas, such as air, at normal pressure. Therefore, disadvantages can be reduced in which the airtight container 3 is adversely affected by expansion of inner gas or the thermoelectric conversion module 4 is deteriorated by heating. The deformation part 313 can be easily arranged since the deformation part 313 of the movable plate part 31 is thinner than the inner rigid part 312 and deformable.

Furthermore, in this Embodiment, the cooling water that flows in the cooling jackets 53a and 53b contacts the elastic plate 70. Since the temperature of the inner rigid part 312 is conducted to the elastic plate 70 and the elastic plate 70 is cooled by the cooling water, radiation of heat can be performed by the elastic plate 70. Therefore, it is desirable that the elastic plate 70 be formed in a fin shape like in this Embodiment, since cooling effect is improved.

### [2-3] Variation of Second Embodiment

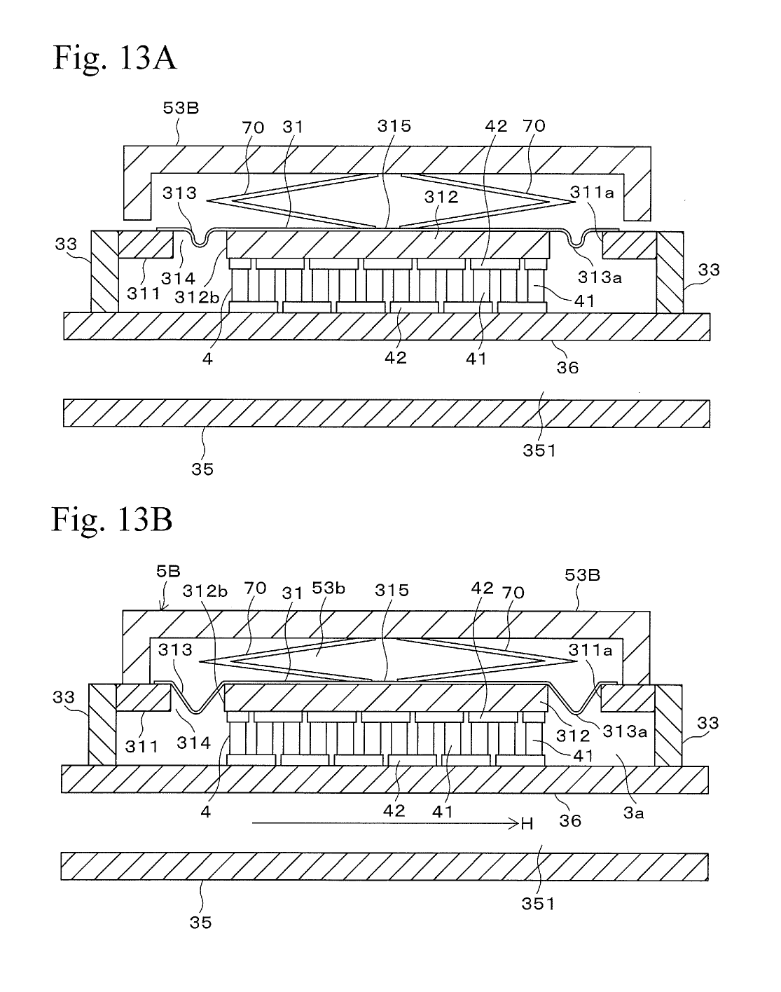

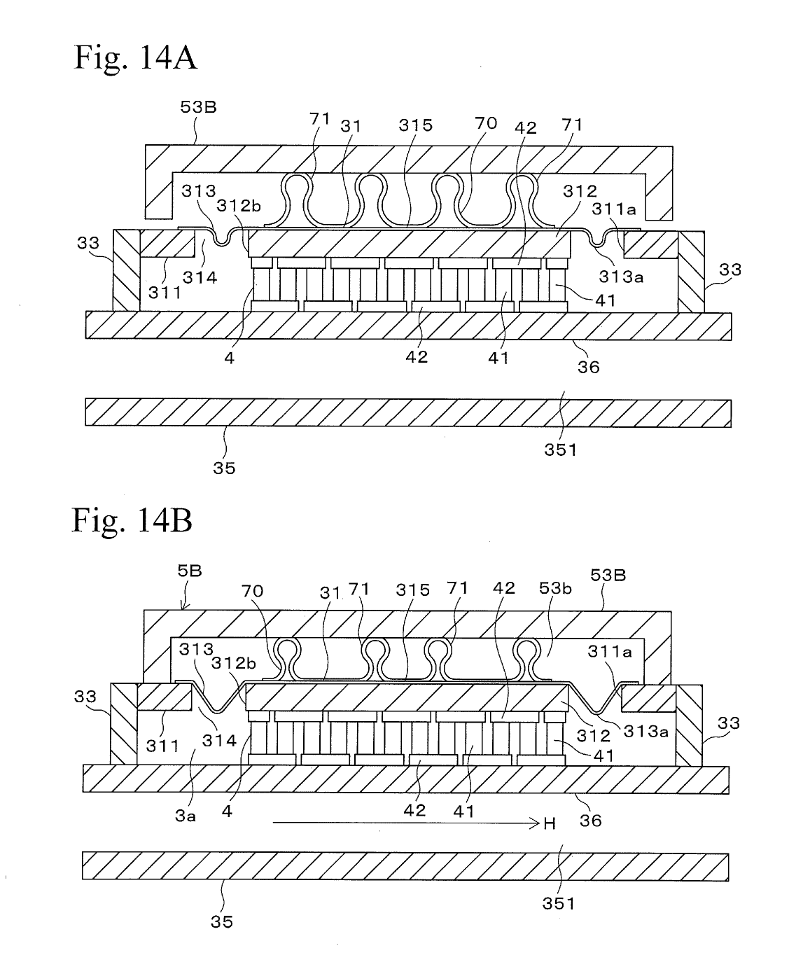

The elastic plate 70 is not limited to the shape of the above Embodiment as far as it presses the inner rigid part 312 toward the thermoelectric conversion module 4. For example, a pair of the elastic plate 70 each having letter V shape cross section being arranged in a horizontally symmetric condition as shown in FIGS. 13A and 13B, or the elastic plate 70 in which the convex line parts 71 having letter Ω shape cross section are arranged in parallel as shown in FIGS. 14A and 14B, can be mentioned. These figures of A show a condition before the cooling case 53B of the end part cooling part 5B is joined to the outer rigid part 311 of the movable plate part 31, and these figures of B show a condition in which the cooling case 53B is joined to the outer rigid part 311 and therefore the inner rigid part 312 of the movable plate part 31 is pressed to the thermoelectric conversion module 4 by the elastic plate 70. As the elastic plate 70, the fin shape is desirable since it contacts to the cooling water thereby obtains heat radiation effect as mentioned above.

### Third Embodiment

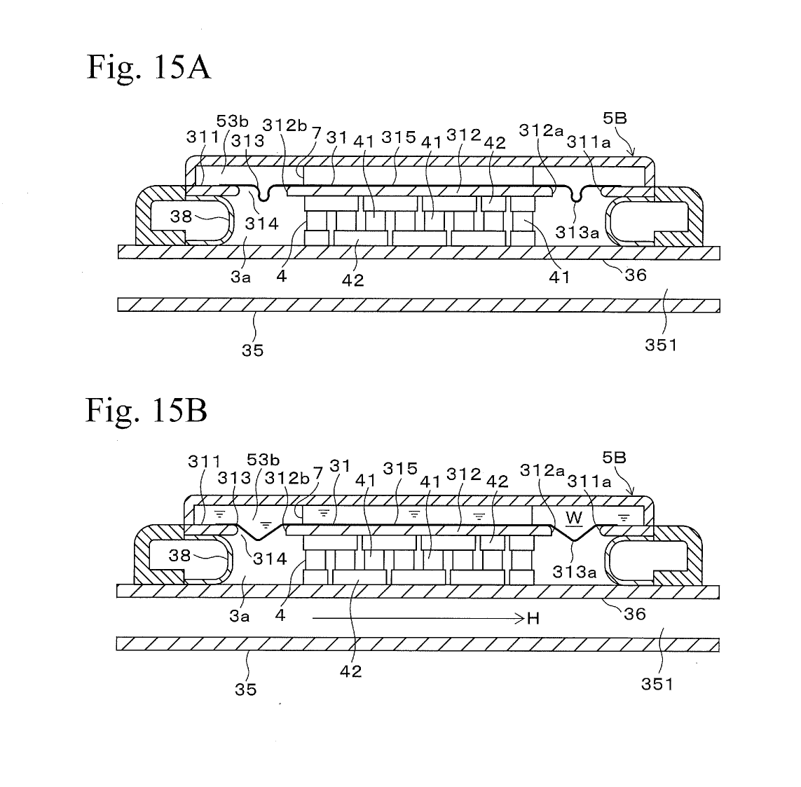

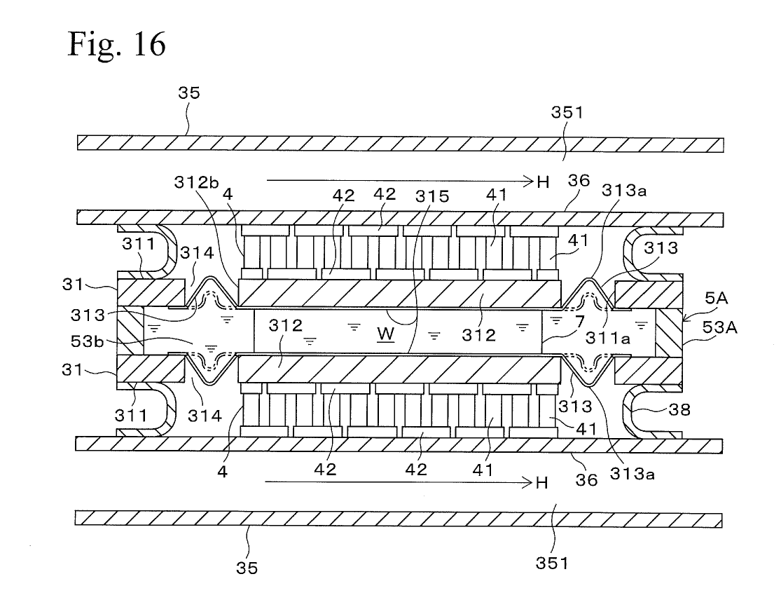

The Third Embodiment of the present invention is explained with reference to FIGS. 15 and 16. The Third Embodiment is characterized by the inner pressure being generated in the cooling jackets 53a and 53b by the cooling water (fluid for cooling) that is supplied in the cooling jackets 53a and 53b in the First Embodiment. The action is explained as follows.

FIG. 15A shows a condition before pressure inside of the end airtight container 3 in which the end part cooling part 5B is arranged is reduced. As shown in FIG. 15B, in a case in which the movable plate part 31 is pressed to the inside by reducing pressure, a convex line part 313a of the deformation part 313 having flexibility is deformed further protruding to the inside, and whereby the inner rigid part 312 is contacted to the thermoelectric conversion module 4. In other words, the deformation of the deformation part 313 realizes that the contact surface of the inner rigid part 312 to the thermoelectric conversion module 4 moves so as to fit to the thermoelectric conversion module 4.

Furthermore, FIG. 16 shows a condition in which pressure of the airtight container 3 of both sides of the intermediate cooling part 5A is reduced. A convex line part 313a of the deformation part 313 having flexibility is similarly deformed protruding to the inside, and thereby the inner rigid part 312 contacts the thermoelectric conversion module 4 (two-dot chain line of the deformation part 313 indicates a condition before reducing pressure).

In this Embodiment, as shown in FIGS. 15B and 16, the movable plate part 31 of the airtight container 3 is cooled by supplying and flowing the cooling water W in each of cooling jackets 53a and 53b. On the other hand, the heating fluid H (for example, exhaust heat gas generated in a factory or garbage incinerator or exhaust gas of vehicles) at high temperature flows through each flow tube 35, from one end to the other end in order to heat the flow tubes 35. Temperature of the movable plate part 31 which is cooled is conducted to outer surface side of the thermoelectric conversion module 4, the outer surface side of the thermoelectric conversion module 4 is cooled. On the other hand, temperature of the inner plate part 36 of the flowing tube 35 which is heated is conducted to inner surface side of the thermoelectric conversion module 4, the inner surface side of the thermoelectric conversion module 4 is heated. The heating fluid H is not scattered by flowing in the hollow part 351, and the inner plate part 36 of the flowing tube 35 is effectively heated. In this way, a temperature difference is produced between the outer surface side and inner surface side of the thermoelectric conversion module 4, whereby the thermoelectric conversion module 4 generates electricity, and the electricity can be obtained from the terminals 43.

In this Embodiment, the cooling water W is always supplied in the cooling jackets 53a and 53b of the each of the cooling parts 5A and 5B in an amount enough to generate inner pressure of the cooling jackets 53a and 53b to a certain extent (for example, 0.1 to 1 MPa). In this way, by generating the inner pressure (pressure of positive direction) in the cooling jackets 53a and 53b by the cooling water W, the inner rigid part 312 of the movable plate part 31 is contacted to the thermoelectric conversion module 4 in a pressed condition by the inner pressure. As a result, the inner rigid part 312 can be fitted to the thermoelectric conversion module 4 in a uniformly pressed condition. In this way, heat conductivity from the cooling parts 5A and 5B to the thermoelectric conversion module 4 via the inner rigid part 312 of the movable plate part 31 is improved, temperature difference imparted to the thermoelectric conversion module 4 is increased, and power generation efficiency is improved.

Furthermore, since the inner rigid part 312 is pressed by using the cooling water W in the cooling jackets 53a and 53b and contacted to the thermoelectric conversion module 4, the inner rigid part 312 can be fitted to the thermoelectric conversion module 4 in a uniformly pressed condition without complicating the device and increasing cost. Furthermore, since a fastening member such as bolt or nut is not used, degree of freedom in planning or designing can be improved and the weight can be reduced.

Furthermore, in this Embodiment, the movable plate part 31 which is the tabular member of cooling side consists of the inner rigid part 312 for contacting to the thermoelectric conversion module 4 and the deformation part 313 having flexibility arranged therearound. Therefore, the condition can be obtained, in which the deformation part 313 is deformed and the inner rigid part 312 contacted to the thermoelectric conversion module 4 surely and uniformly. Furthermore, by making the rigid part as a part fitting to the thermoelectric conversion module 4, the parts surely contacts to the thermoelectric conversion module 4 via a surface without being deformed, and uniformly pressed condition to the thermoelectric conversion module 4 is easily obtained.

In addition, in this Embodiment, the inner rigid part 312 of the movable plate part 31 is contacted to the thermoelectric conversion module 4 in a pressed condition also by reducing pressure inside of the airtight container 3 in addition to the inner pressure in the cooling jackets 53a and 53b. Therefore, fitting property of the inner rigid par 312 on the thermoelectric conversion module 4 can be further improved. In addition, since pressure inside of the airtight container 3 is reduced, inside of the airtight container 3 is difficult to be heated compared to a case in which the inner space 3a contains gas such as air at normal pressure. Therefore, disadvantage can be reduced in which the airtight container 3 is adversely effected by expansion of inner gas or the thermoelectric conversion module 4 is deteriorated by heating.

### Fourth Embodiment

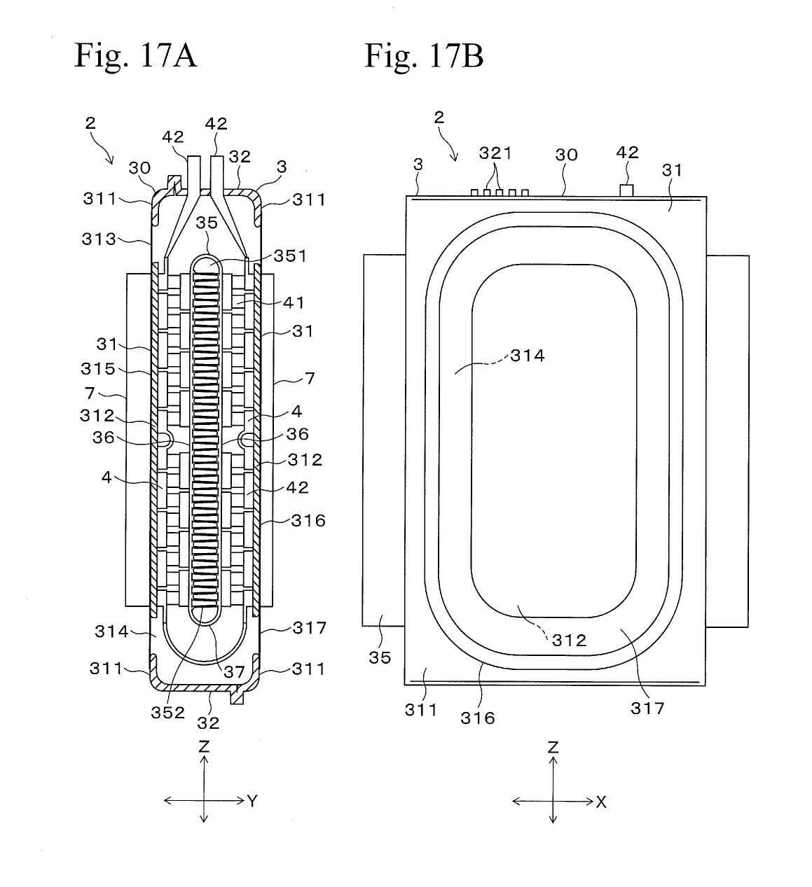

Next, the Fourth Embodiment of the present invention is explained with reference to FIGS. 17 to 19. The Fourth Embodiment has an elastic part 317 arranged instead of the deformation part 313, in the airtight container 3 of the First Embodiment. An airtight container 3 of the Fourth Embodiment is explained as follows.

### [4-1] Structure of Airtight Container

As shown in FIG. 17, a movable plate part 31 which constructs a housing 30 of the airtight container 3 of the Fourth Embodiment includes an outer rigid part 311 that is formed to have a rectangular frame shape as an outer shape; an inner rigid part 312 which has the same thickness as that of the outer rigid part 311 and which is arranged inside of the outer rigid part 311; and the elastic part 317 which is thinner than the rigid parts 311 and 312 and which is arranged so as to seal a gap 314 which is a gap of a certain width and is formed between the outer rigid part 311 and the inner rigid part 312.

Inner edge 311 a of the outer rigid part 311 is formed approximately in an oval shape, and outer edge 312a of the inner rigid part 312 is formed approximately in an oval shape and is arranged having the certain gap 314 from the inner edge 311 a of the outer rigid part 311. On the outer surface of the inner rigid part 312, a spring plate 316 having elasticity is joined by a joining means such as brazing. This spring plate 316 has a size sufficient to cover the gap 314 between the rigid parts 311 and 312 and to reach the outer surface of the outer rigid part 311, and outer edge part thereof is joined to the outer surface of the outer rigid part 311 by a joining means such as brazing.

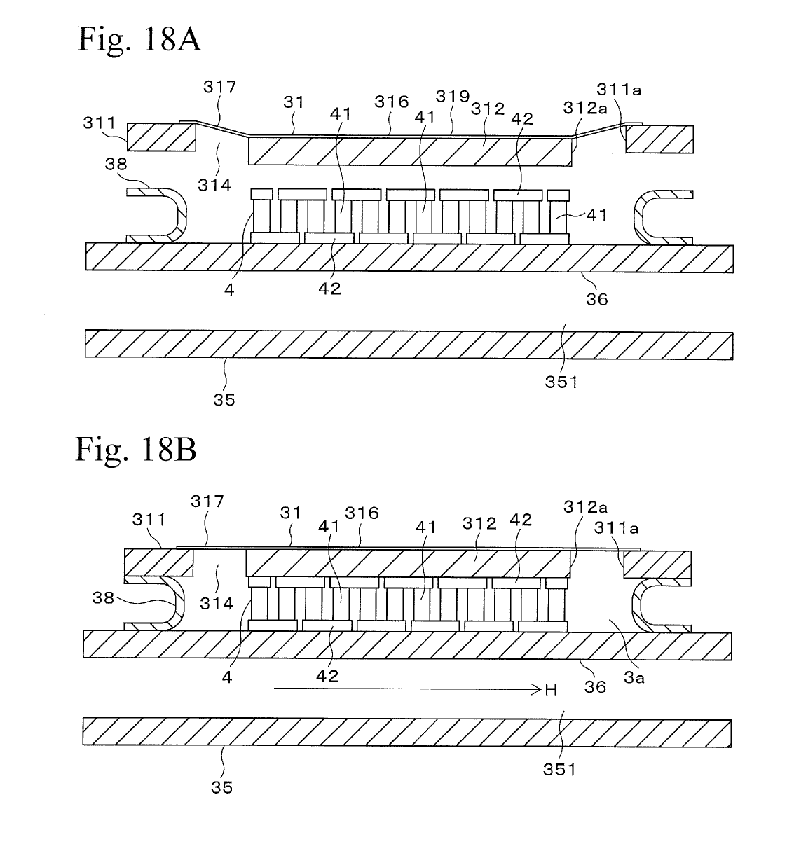

The region of the spring plate 316 that covers over the gap 314 forms the elastic part 317 having approximately a circular shape. This elastic part 317 is arranged in a condition existing from the outside of the outer edge 312a of the inner rigid part 312 to the outside of the inner edge 311a of the outer rigid part 311, and in a free condition before assembling as the airtight container 3 having the thermoelectric conversion module 4 inside, as shown in FIG. 18A, it inclines to the inside. That is, the spring plate 316 is bent to the inside at the outer edge 311 a of the outer rigid part 311, extends straight, and is again bent at the outer edge 312a of the inner rigid part 312 so as to be joined to an outer surface of the inner rigid part 312. Therefore, the entirety of the movable plate part 31 of the housing 30 is in a condition in which concave region 319 is formed from the elastic part 317 to the inner rigid part 312 in a free condition of the elastic part 317.

Multiple outlets for pressure reducing and sealing 321 are arranged at an end plate part 32 upward of the airtight container 3, and pressure of the inner space 3a inside of the airtight container 3 is reduced via these outlets for pressure reducing and sealing 321.

Both ends in the Z direction of the outer rigid part 311 are formed in a condition in which they are unified with the end plate part 32. That is, the outer rigid parts 311 of both sides are integrally formed with the upper and lower pair of the end plates part 32, and the inner rigid part 312 is joined to the outer rigid part 311 via the spring plate 316, so as to construct the housing 30. The inner rigid part 312 has a size covering over the thermoelectric conversion module 4, and is in a condition contacting the entire surface of one side of the thermoelectric conversion module 4.

In the airtight container 3 having the above structure, when assembling by joining the inner surface of the outer rigid part 311 of the movable plate part 31 to the sealing cover 38 in a condition in which the thermoelectric conversion module 4 is arranged inside, as shown in FIG. 18B, the inner surface of the inner rigid part 312 of the movable plate part 31 contacts the thermoelectric conversion module 4, the elastic part 317 is elastically deformed to the outside, the concave region 319 disappears, the outer rigid part 311 and the inner rigid part 312 become in almost the same plane, and the elastic part 317 becomes almost parallel to the rigid parts 311 and 312. In this assembled condition, the inner rigid part 312 is strongly contacted to the thermoelectric conversion module 4 and fits uniformly to the thermoelectric conversion module 4, by repulsive force of the elastic part 317 that is deformed. It should be noted that the rigid parts 311 and 312 exist in almost the same plane in this Embodiment; however, the relationship of position of the rigid parts 311 and 312 is not limited to this, and a structure in which one of them is aligned to the inside and they are connected by the spring plate 316, can be selected.

Next, the airtight container 3 is sealed airtight by drawing out the air inside from an outlet for pressure reducing and sealing 321 so as to reach a predetermined pressure (about 1 to 100 Pa for example), and by welding the outlet for pressure reducing and sealing 321.

Structure and power generating action of each cooling part (intermediate cooling part 5A and end part cooling part 5B) are the same as in the First Embodiment.

### [4-2] Action and Effect of Airtight Container

In this Embodiment, the inner rigid part 312 of the movable plate part 31 of the airtight container 3 contacts the thermoelectric conversion module 4 in a pressed condition by repulsive force of the elastic part 317 of the spring plate 316, and fits uniformly. Thus, heat conductivity from the cooling parts 5A and 5B to the thermoelectric conversion module 4 via the inner rigid part 312 is improved, the temperature difference imparted to the thermoelectric conversion module 4 increases, and power generation efficiency is improved.

Since the inner rigid part 312 which is the tabular member of the cooling side fits to the thermoelectric conversion module 4 by repulsive force of the elastic part 317 of the movable plate part 31 without using a member for fastening such as a tie rod or nut, unlike in a conventional technique, the inner rigid part 312 can be fitted in uniformly pressed condition on the thermoelectric conversion module 4 without complication and high cost. Furthermore, since the member for fastening, such as a bolt and nut, is not used, freedom in planning or designing can be improved and the weight can be reduced.

The inner rigid part 312 which fits to the thermoelectric conversion module 4 in a pressed condition by elasticity of the elastic part 317 of the movable plate part 31, is set to have a thickness so that it will not deform even if pressed to the thermoelectric conversion module 4 side. Therefore, the inner rigid part 312 is prevented from being deformed, and the inner rigid part 312 can reliably contacted to the thermoelectric conversion module 4 by a surface and fit uniformly.

In addition, since pressure in the airtight container 3 is reduced, the inside of the airtight container 3 is difficult to heat compared to a case in which the airtight container contains gas, such as air, at normal pressure. Therefore, disadvantages can be reduced in which the airtight container 3 is adversely affected by expansion of inner gas or the thermoelectric conversion module 4 is deteriorated by heating.

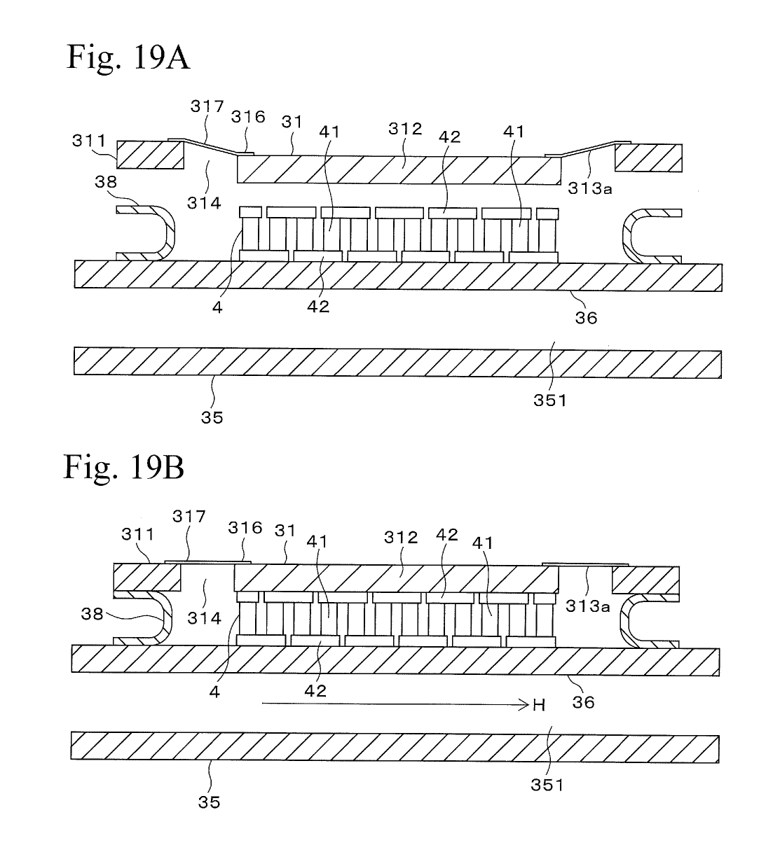

In the present Embodiment, various variations are possible. For example, as shown in FIGS. 19A and B, the spring plate 316 which forms the elastic part 317 can be formed to be circular having a certain extent of width to cover the gap 314 between the outer rigid part 311 and the inner rigid part 312, instead of one which covers the entirety of the outer surface of the inner rigid part 312.

1. A thermoelectric conversion generating device comprising:
an airtight container in which a tabular member of a heating side and a tabular member of a cooling side are arranged, and
a thermoelectric conversion module contained in the airtight container in a condition that the module is arranged between the tabular member of the heating side and the tabular member of the cooling side,
wherein the thermoelectric conversion module generates electricity by producing a temperature difference in the thermoelectric conversion module by heating the tabular member of the heating side and cooling the tabular member of the cooling side at the same time,
at least one of the tabular member of the heating side and the tabular member of the cooling side is a tabular member of a movable side which contacts to the thermoelectric conversion module in a pressed condition due to a pressure difference between inside and outside of the airtight container that occurs by reducing pressure inside of the airtight container, and
the tabular member of the movable side comprises:
a rigid part which is rigid and contacted to the thermoelectric conversion module, and
a deformation part which is formed while being connected to the rigid part, is deformed by the pressure difference, and renders the rigid part contacting to the thermoelectric conversion module by the deformation of itself

2. The thermoelectric conversion generating device according to claim 1, wherein tabular member thickness of the deformation part is smaller than that of the rigid part, and therefore the deformation part can be deformed.

3. The thermoelectric conversion generating device according to claim 1, wherein the tabular member of the cooling side is the tabular member of the movable side, and a fin for promoting cooling is arranged on the rigid part.

4. The thermoelectric conversion generating device according to claim 1, wherein the deformation part is arranged in a condition extending laterally from outside of peripheral surface of the rigid part which is opposite side to the thermoelectric conversion module side, and the peripheral surface of the rigid part is formed into an approximately tapered shape projecting laterally from the outside to the inside which is the thermoelectric conversion module side.

5. The thermoelectric conversion generating device according to claim 1, wherein the airtight container comprises a hollow part surrounded by the tabular member of the heating side, the thermoelectric conversion module is arranged around the hollow part, the tabular member of the cooling side is arranged outside of the thermoelectric conversion module, and
wherein a heating fluid flows through the hollow part so as to heat the tabular member of heating side.

6. The thermoelectric conversion generating device according to claim 1, wherein the thermoelectric conversion module is not joined to the rigid part.

7. The thermoelectric conversion generating device according to claim 1, wherein the deformation part is an elastic part which is elastically deformed so that the rigid part is elastically pressed and contacted to the thermoelectric conversion module side.

8. The thermoelectric conversion generating device according to claim 1, further comprises an elastic member which renders at least one tabular member of the tabular member of the heating side and the tabular member of the cooling side being pressed and contacted to the thermoelectric conversion module.

9. The thermoelectric conversion generating device according to claim 8, wherein a pressing plate is arranged on outer surface side of the tabular member which is pressed and contacted to the thermoelectric conversion module by the elastic member, and the elastic member is sandwiched between the pressing plate and the tabular member.

10. The thermoelectric conversion generating device according to claim 9, wherein the elastic member is joined to one of the tabular member and the pressing plate, and is not joined to the other of them.

11. The thermoelectric conversion generating device according to claim 8, wherein the tabular member is the tabular member of cooling side, a cooling medium is flowed between the tabular member and the pressing plate, and the cooling medium contacts to the elastic member.

12. The thermoelectric conversion generating device according to claim 11, wherein the elastic member is formed into a fin shape for promoting cooling.

13. The thermoelectric conversion generating device according to claim 12, wherein the elastic member is formed into a fin shape having cross section of corrugated, letter V shaped, letter U shaped, or letter Ω shaped.

14. The thermoelectric conversion generating device according to claim 1, wherein the tabular member of the movable side is the tabular member of the cooling side,
a cooling chamber is arranged in which a cooling fluid is supplied and contacted to the tabular member of the cooling side, and
the rigid part of the tabular member of the cooling side is contacted to the thermoelectric conversion module in a pressed condition due to inner pressure generated in the cooling chamber by the cooling fluid.
